(19) United States
(12) Patent Application Publication
(10) Pub. No.: US 2011/0146753 A1
(43) Pub. Date: Jun. 23, 2011

(54) SOLAR ENERGY GENERATION SYSTEM

(75) Inventors: Victor F. Johnson, Fountain Valley, CA (US); Russell P. Johnson, Huntington Beach, CA (US)

(73) Assignee: Victor F. Johnson, Fountain Valley, CA (US)

(21) Appl. No.: 12/968,612

(22) Filed: Dec. 15, 2010

Related U.S. Application Data
(60) Provisional application No. 61/287,578, filed on Dec. 17, 2009.

(51) Int. Cl. H01L 31/052; H01L 31/024; H01L 31/02

(52) U.S. Cl. 136/246; 136/252; 136/259

(57) ABSTRACT

Embodiments of a solar energy generation system are disclosed. The solar energy generation system may be adapted for use with a right of way or may be adapted to at least partially cover buildings or objects. In one embodiment adapted for use with a right of way, the solar energy generation system includes a plurality of support members that extend over at least some of the right of way and are configured to support an array of solar cell modules. The solar cell modules may be elongated units that are disposed substantially parallel to each other and to the local direction of the right of way. The solar cell modules can include one or more photovoltaic panels on an upper surface and can have a lower surface that is aerodynamically shaped to provide a downward aerodynamic force when wind flows past the solar cell module.

### CROSS-REFERENCE TO RELATED APPLICATIONS

This application claims the benefit under 35 U.S.C. §119(e) of U.S. Provisional Patent Application No. 61/287,578, filed Dec. 17, 2009, entitled “SOLAR ENERGY GENERATION SYSTEM,” the entire disclosure of which is hereby incorporated by reference herein.

### BACKGROUND

1. Field

The present disclosure generally relates to a solar energy generation system.

2. Description of the Related Art

Solar power can be produced by collecting the sun's light and converting it into electricity. For example, solar energy generation systems can use solar collectors to concentrate sunlight onto photovoltaic cells, which convert the sun's radiant energy into electrical energy. Solar energy generation systems may use a large number of solar collectors or photovoltaic cells to achieve a desired level of electrical power generation. The task of constructing and maintaining solar energy generation systems has become increasingly complicated.

### SUMMARY

Various non-limiting aspects of the present disclosure will now be provided to illustrate features of the disclosed apparatus, systems, and methods.

In one aspect, a solar energy generation system may be adapted for use with a right of way. The solar energy generation system may include a plurality of support structures disposed along a length of a right of way. Each of the plurality of support structures can be spaced from each other along the length of the right of way. Each of the support structures may comprise a first riser portion that can be disposed on a first side of the right of way, a second riser portion that can be disposed on a second side of the right of way, and a span portion that can extend from the first riser portion and the second riser portion above a surface of the right of way.

The solar energy generation system may also include a plurality of solar cell modules that can be disposed substantially parallel to each other along the length of the right of way. Each solar cell module may be at least partially supported above the right of way by at least some of the span portions of the plurality of support structures. Each solar cell module may comprise one or more photovoltaic panels that can be configured to receive sunlight and generate electricity. In some implementations, each solar cell module may have a cross-sectional shape configured to generate an aerodynamic force directed toward the surface of the right of way in the presence of airflow past the solar cell module.

The solar energy generation system may also include one or more deflectors disposed adjacent at least some of the first riser portions that are disposed on the first side of the right of way. The one or more deflectors may be disposed substantially parallel to the length of the right of way. The one or more deflectors can be configured to at least partially deflect airflow away from the surface of the right of way.

In various implementations, the right of way may comprise a waterway. The waterway may be a canal, river, stream, channel, aqueduct, drainage system, water bridge, or water course that holds or transports water. In other implementations, the right of way may comprise a public or private right of way including, but not limited to, streets, roads, highways, sidewalks, walkways, pedestrian or bicycle paths, parking areas, bridges, railroad lines, magnetic levitation vehicle transport systems, public transportation networks (e.g., subways, shuttle ways, light rail lines, people movers, or mass transit systems), pipeline systems for transporting fluids (e.g., fuel, petroleum, oil, gas, water, slurries, sewage, or other liquids or gases), electric power transmission systems (e.g., high-tension power lines),

In another aspect, a solar assembly comprises a first support member that has a first portion disposed above a surface and a second support member that can be spaced from the first support member along a first direction. The second support member can have a second portion disposed above the surface. The solar assembly can further include a solar array that comprises a plurality of solar cell modules. Each solar cell module may comprise at least one photovoltaic panel. Each solar cell may further comprise a first end portion and a second end portion. The first end portion may be mounted or attached to the first portion of the first support member, and the second end portion may be mounted or attached to the second portion of the second support member. Each of the solar cell modules may be oriented substantially parallel to the first direction. Each solar cell module can have a cross-sectional shape in a plane perpendicular to the first direction. In some implementations, the cross-sectional shape may be configured to generate an aerodynamic force directed toward the surface in the presence of an airflow that at least partially flows perpendicular to the first direction.

In various implementations, the solar energy assembly may be used with spaces including, but not limited to, rights of way, bodies of water or water passages, areas of vehicular traffic, pedestrian routes, track or rail based transportation systems, pipeline systems or traces, high tension electrical power transmission systems, bridges, dams, swimming pools, parking areas, airfields, waste processing stations, storage and commercial facilities, buildings, cargo, or objects.

In another aspect, a kit of components can be adapted for assembly of a solar energy generation system. The kit can include at least one support structure. The support structure can comprise at least one riser and at least one span member. The riser can have a first end portion configured for mounting or attachment to a surface and can have a second end portion configured to at least partially support the span member. The kit may include at least one elongated solar cell module that has a longitudinal axis. The solar cell module may have at least one end portion configured to be mounted or attached to a span member. The solar cell module can have an upper portion and a lower portion. The upper portion can be configured to at least partially support at least one photovoltaic panel. The solar cell module may have a shape in a plane perpendicular to the longitudinal axis that is configured to generate an aerodynamic force in the presence of air flowing at least partially perpendicular to the longitudinal axis of the solar cell module. The aerodynamic force may have a component directed away from the upper portion of the solar cell module.

In various applications, the kit of components may be used for any of the rights of way, objects, structures, uses, implementations, or embodiments described herein.

For purposes of this summary, certain aspects, advantages, and novel features of the inventions are summarized. It is to be understood that not necessarily all such advantages may be achieved in accordance with any particular embodiment of the invention. Thus, for example, those skilled in the art will recognize that the inventions disclosed herein may be embodied or carried out in a manner that achieves one advantage or group of advantages as taught herein without necessarily achieving other advantages as may be taught or suggested herein.

### BRIEF DESCRIPTION OF THE DRAWINGS

FIG. 1A is a perspective view schematically illustrating an embodiment of a solar energy generation system adapted for use along a waterway.

FIG. 1B is a cross-section view schematically illustrating another embodiment of a solar energy generation system adapted for use along a waterway.

FIG. 1C is a cross-section view schematically illustrating an embodiment of a solar cell module.

FIG. 2 is a perspective view schematically illustrating another embodiment of a solar energy generation system.

FIG. 3 schematically illustrates an example of a kit of components that may be used for assembly of an embodiment of a solar energy generation system.

FIG. 4 schematically illustrates an example of assembly of an embodiment of a solar energy generation system.

Throughout the drawings, reference numbers may be re-used to indicate a general correspondence between referenced elements. The drawings are provided to illustrate example embodiments described herein and are not intended to limit the scope of the disclosure.

### DETAILED DESCRIPTION

### Overview

In the past, if solar energy generating systems were proposed for use with structures, canals, aqueducts, waterways or roadways, or other rights of way, one possible option was to simply take a solar energy generation system adapted for other uses and mount it directly on the structure, canal, aqueduct, waterway, roadway, or other right of way. Another option was to purchase a tract of land in a remote location on which to build the solar energy generation system and transmit the generated power over wires to the point where the power was to be used, accommodating the line losses that can result from power transmission over distance. Such solar energy generation systems could use solar reflectors, solar concentrating systems to heat carrier fluids, pumps and other heavy equipment. While such approaches could gather radiant solar energy, use of the systems often required that the structure on which the solar energy generation system was built to support substantially more weight than the structure was originally designed to support, which could lead to difficulties in assembly or maintenance of the solar energy generation system.

Some solar energy generation systems that have been proposed utilize a collector to concentrate solar energy on a pipe containing a fluid in order to heat the fluid and then pump it to a device that would use the stored heat to generate electricity. This design approach typically utilizes a system of moving parts, which must be maintained regularly. Also, for some systems used with waterways, membranes that seal the water from air have been used to reduce or eliminate evaporation losses of the transported water. Such membranes may require maintenance during their useful life, may block access to the waterway, and may increase the complexity and cost of the solar energy generation system.

Accordingly, solar energy generation systems will be disclosed that address some of the forgoing problems or other problems. As will be described further below, embodiments of the disclosed solar energy generating systems may be adapted for use with many different types of spaces including, but not limited to, rights of way, bodies of water or water passages, areas of vehicular traffic, pedestrian routes, track or rail based transportation systems, pipeline systems or traces, high tension electrical power transmission systems, bridges, dams, swimming pools, parking areas, airfields, waste processing stations, storage and commercial facilities, buildings, cargo, or objects.

### Example Embodiments of Solar Energy Generation Systems for Waterways

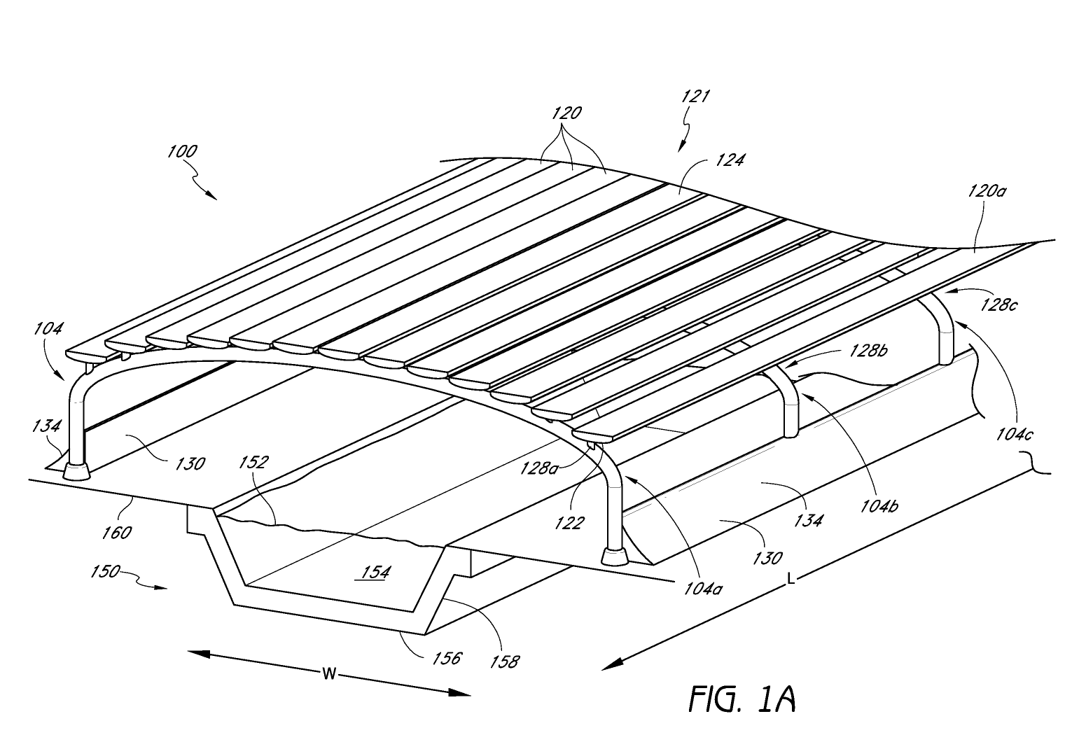

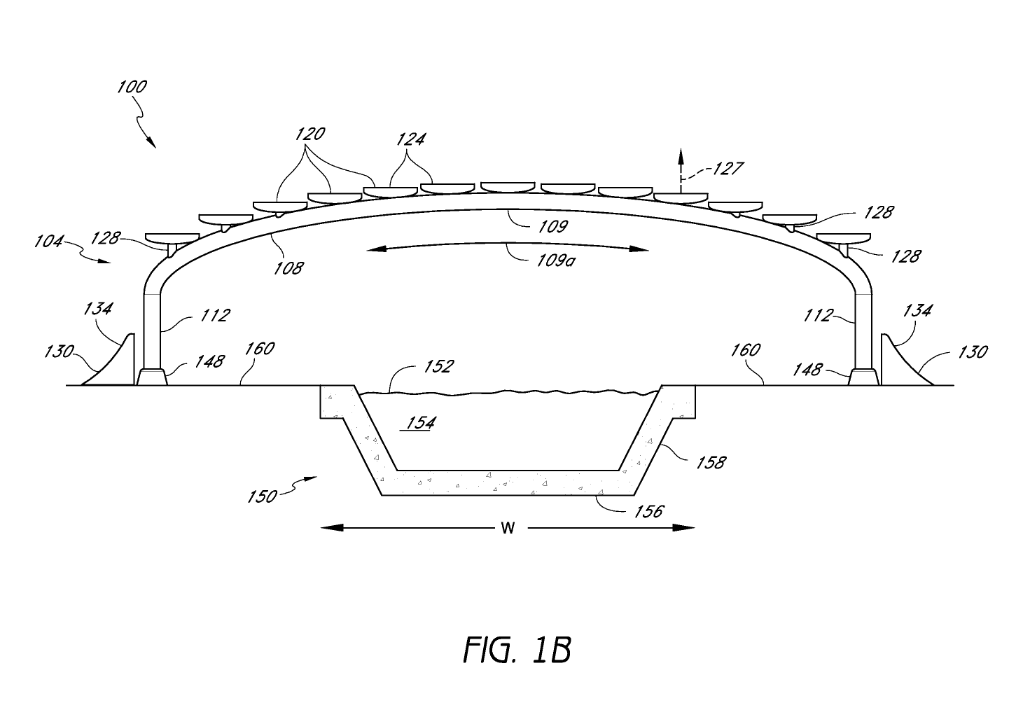

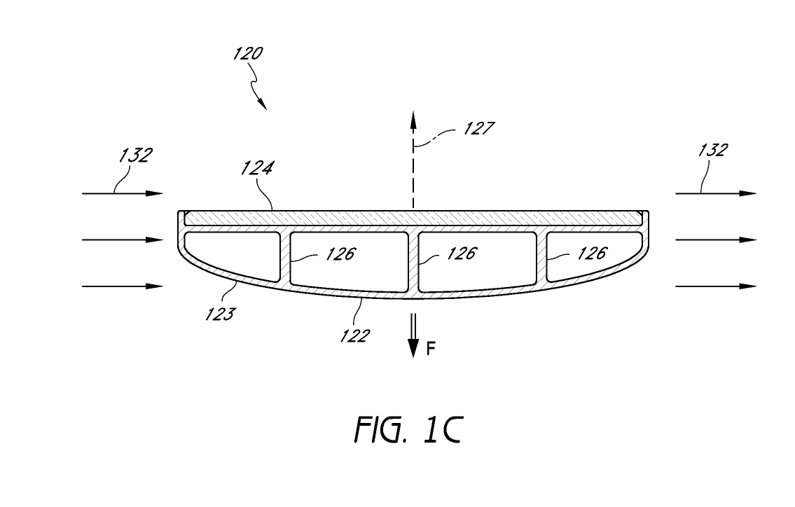

FIG. 1A is a perspective view schematically illustrating an embodiment of a solar energy generation system 100 adapted for use along a waterway 150. The waterway 150 can be a canal, river, stream, channel, aqueduct, drainage system, water bridge, or water course that holds or transports water 154. In one implementation, the solar energy generation system 100 can be adapted for use along the California Aqueduct. Generally, the water 154 in the waterway 150 has an open surface 152 that may be subject to evaporative losses and other environmental conditions. The waterway 150 may include sidewalls 158 and a bottom surface 156 to support the water 154. A surface 160 adjacent the waterway 150 can be used to provide access to or along the waterway 150 and may be developed or undeveloped. For example, portions of the surface 160 may comprise a maintenance road, pedestrian or bicycle path, a walkway, or other man-made route or may comprise relatively undeveloped ground or terrain. The solar energy generation system 100 may be disposed along a length L of the waterway 150, which may have a width W (e.g., measured between the outermost portions of the sidewalls 158).

The solar energy generation system 100 schematically illustrated in FIG. 1A comprises one or more support structures 104 configured to support one or more solar cell modules 120. In the illustrated embodiment, an array 121 of solar cell modules 120 can be supported by one or more support structures 104 such that a given solar cell module 120 may be oriented substantially parallel to and spaced from one or more adjacent solar cell module(s). The solar cell modules 120 can be oriented substantially perpendicular to the support structure 104 (see, e.g., FIG. 1B) such that the solar cell modules 120 are oriented generally parallel to the direction of the waterway 150 in their vicinity. The solar cell modules 120 may be formed as substantially continuous elongated members or may be multiple discrete units that are mounted or attached to the support structures 104.

The solar cell modules 120 (described further with reference to FIG. 1C) can include one or more solar panels 124 (e.g., photovoltaic cells, photovoltaic panels, or arrays of photovoltaic cells or panels) that can receive light from the sun and generate electricity. The solar panels 124 may comprise a substantially transparent cover (e.g., glass or plastic) that can protect the photovoltaic cells or panels from damage. In some implementations, the cover may have an arcuate shape (e.g., convex) to at least partially provide desired aerodynamic characteristics of the solar cell module 120 or to reduce the likelihood that rain pools or debris collects over the solar panels 124. The solar cell modules 120 can be configured to be mounted or attached to one or more of the support structures 104. The solar energy generation system 100 may include wiring and circuitry to transmit the generated electrical power to a desired electrical component or subsystem such as, for example, an electrical power storage system (rechargeable batteries, capacitors, etc.), an electrical power transmission system (e.g., electrical power lines for an electrical power grid), an electrical power management system (e.g., load management or shedding, electrical capacity scheduling). In some implementations, the wiring (or other electrical components) can advantageously be disposed in the support structure 104 (e.g., within tubular members forming the support structure) to reduce the likelihood of exposure of the wiring or electrical components to weather conditions.

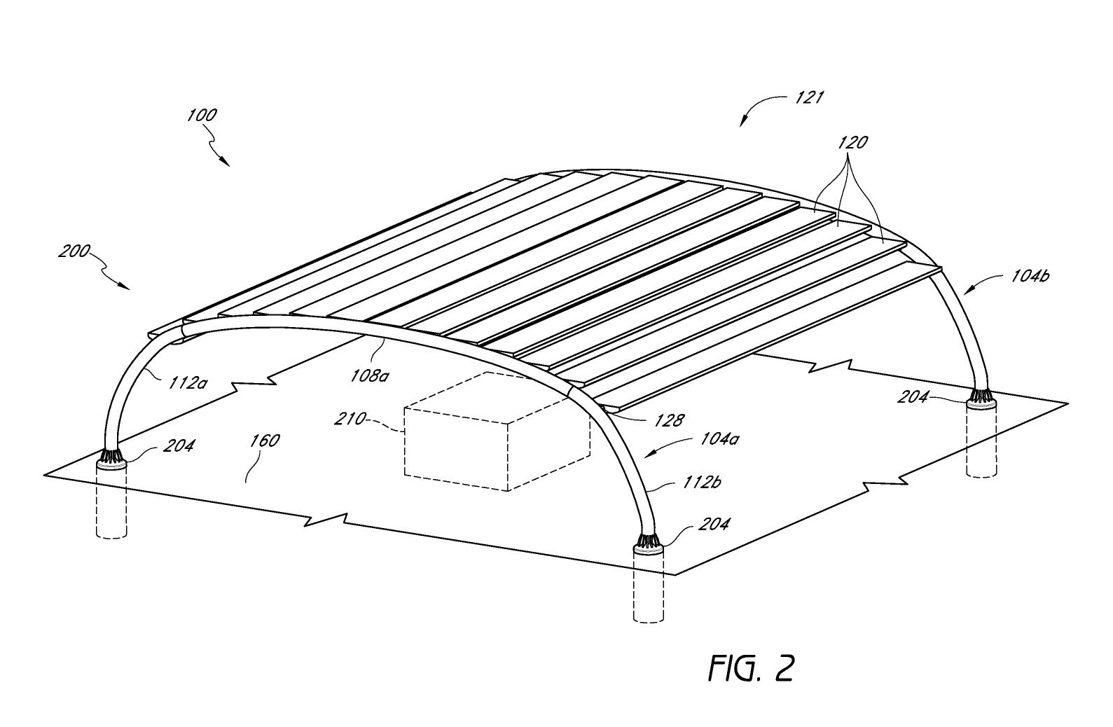

A plurality of support structures 104a, 104b, and 104c can be spaced apart and used to support the solar cell modules 120 along a length of the waterway 150. For example, in one implementation, a solar cell module 120 can be supported by the support structures 104a, 104b, and 104c via one or more mounting fixtures 128a, 128b, 128c, respectively. In the embodiment illustrated in FIG. 1A, the mounting fixtures 128a-128c may be attached or formed on a lower surface 122 of the solar cell module 120 and used to mount the solar cell module 120 to the support structures 104a-104c. In other embodiments, the solar cell modules 120 may be mounted or attached to the support structures 104 differently (see, e.g., FIG. 2).

In some implementations, the support structure 104 and spacing between adjacent structures 104 can be designed to support static loads of the support structure 104 and the array 121 of solar cell modules 120 as well as expected dynamic loads caused by weather (e.g., wind, rain, or snow), vibration, earth movement, or other environmental conditions. In some implementations, dozens, hundreds, thousands, or tens of thousands of support structures 104 may be used to support the array 121 of solar cell modules 120 along some or all of the waterway 150. In some such implementations, the array 121 of solar cell modules 120 may include one, two, five, ten, thirteen, fifteen, twenty, twenty-four, or more solar cell modules 120.

Various properties of the solar energy generation system 100 including, for example, the number or spacing of the support structures 104, the number of solar cell modules 120 in the array 121, the widths, lengths, heights of individual modules 120, can be selected based at least in part on the properties of the particular waterway 150 or the surface 160, or desired goals for solar energy generation or for reduction of evaporation from the waterway 150. Various such properties may be selected so that the system 100 presents a reduced profile to environmental conditions (e.g., wind, rain, or snow) or presents a visually attractive appearance. In some implementations, the design of the array of solar cell modules 120 schematically illustrated in FIG. 1A can be chosen to substantially cover the water 154 in the waterway 150, which may provide shade to the water 154 and which may reduce evaporation of the water 154 from the waterway 150. In some implementations, edge portions of the solar cell modules 120 may be substantially adjacent each (e.g., touching or nearly touching, or above or below each other as shown in FIG. 1B) so that the array 121 of solar cell modules 120 provides substantially continuous cover (as seen from above) to the water 154 in the waterway 150. Various properties of the solar energy generation system 100 can change along the length of the waterway 150 so that the system 100 can be adapted to the local characteristics of the waterway 150 (e.g., width of the water or the waterway, available space above or adjacent the waterway), desired solar energy production, desired reduction in water evaporation, reduced profile in view of local environmental conditions, and so forth.

As schematically illustrated in FIG. 1A, one or more deflectors 130 may be disposed substantially longitudinally along or adjacent one or both sides of the solar energy generation system 100. For example, the deflectors 130 can be elongated units that can be aligned substantially parallel to the waterway 150. The deflectors 130 have a surface 134 that can be shaped to help direct airflow near the surface 160 (e.g., cross-winds) upward toward upper portions of the solar energy generation system 100, where the airflow may join the general pattern of airflow over or around the system 100. In embodiments of the system 100 that use the deflectors 130, airflow near the surface 160 may be directed away from the water surface 152, which may reduce flow of dry air over the water surface 152 and/or leave a relatively quiescent layer of saturated air adjacent the water surface 152. Since water evaporation rates into saturated air are generally low under many atmospheric conditions, use of the deflectors 130 advantageously may reduce evaporation of water from the waterway 150.

Some of the deflectors 130 may include an access opening (e.g., a gate) to permit access to the waterway 150. In some implementations, a deflector 130 is not used along a portion of the solar energy generation system to provide access to the waterway 150 through the portion.

Embodiments of the solar energy generation system 100 may have few or no moving parts, which advantageously may lead to an extended service life of the system 100, requiring little or minimum maintenance. Additionally, assembly or maintenance costs of certain such embodiments may be lower than for solar power systems comprising more moving parts (e.g., fluid transport systems for circulating or condensing water heated by solar collectors). Further, certain such embodiments may utilize little or no fuel, so that operation of the solar energy generation system 100 may be “green” and produce relatively little or no pollution. Accordingly, certain such embodiments may contribute to the development of renewable energy resources (e.g., solar energy), may provide more efficient utilization and conservation of energy resources (e.g., reduced reliance on petroleum-based energy sources, increased reliance on solar power), and may lead to reduction in greenhouse gas emissions due to increased utilization of renewable, solar energy rather than on energy from sources producing greenhouse gases.

FIG. 1B is a cross-section view schematically illustrating another embodiment of a solar energy generation system 100 adapted for use along the waterway 150. In the implementation shown in FIG. 1B, the support structure 104 comprises two risers 112 and a span member 108. The risers 112 can be mounted, anchored, or attached to the surface 160 adjacent the waterway 150 (e.g., using mounting brackets 148). In some implementations, ends of one or both risers 112 are mounted, anchored, or attached to a concrete foundation or footer in, on, or underneath the surface 160. A possible advantage of mounting the risers 112 away from the sidewalls 158 of the waterway 160 is that the structural integrity of the waterway 160 may not be substantially affected by installation of the solar energy generation system 100. In other embodiments, one or both risers 112 can be mounted in or on portions of the waterway 150, for example, in or on portions where the waterway has sufficient structural strength to support the structures 104 and solar cell modules 120.

One or both risers 112 can be mounted substantially vertically (e.g., substantially perpendicular to the surface 160) or can be mounted at a non-perpendicular angle with respect to the surface 160 (e.g., risers slanted at an angle of, for example, 80 degrees, 70 degrees, 60 degrees, or some other angle with respect to the surface 160). One or both risers 112 can be substantially straight or can be curved (see, e.g., FIG. 2). The height of the risers 112 can be selected to provide desired clearance below the span member 108. For example, as will be discussed further below (see, e.g., FIG. 2), in other implementations, pipelines, railways, vehicles, cargo, objects, or buildings can be disposed at least partially under the solar energy generation system 100, and the risers 112 (and/or the span member 108) can be configured to provide sufficient clearance. In various embodiments, the risers 112 can have a height in a range from about 1 meter to about 10 meter, from about 3 meter to about 8 meter, from about 4 meter to about 6 meter, or some other range. The height of the risers can be about 7 meter in one embodiment.

In some implementations, more than two risers 112 may be used to support the span member 108. For example, a third riser 112 can be used to help support the central section of the span member 108. In other implementations, no risers 112 are used, and ends (or other portions) of the span member 108 may be supported by structures, terrain, and so forth that may be adjacent the solar energy generation system 100. In other implementations, a single riser 112 may be used to support the span member 108, which may be cantilevered.

The span member 108 can be a substantially straight member or may have one or more portions that can be curved. In some embodiments, portions of the span member 108 can have a shape that is a portion of a curve that is substantially elliptical or oval. For example, a portion 109a surrounding the center 109 of the span member 108 may be arcuate with a shape that is a portion of a substantially elliptical or oval curve. In some cases, substantially the entire length of the span member 108 is a portion of an elliptical or oval curve. Other shapes for the support structure 104 can be used. For example, the support structure 104 (or the span member 108) may be shaped like an arch. A possible advantage of a curved (or arched) span member 108 is that the support structure 104 may provide additional clearance (above the upper end of risers 112) for objects disposed at least partially under the solar energy generation system 100. In some implementations, the shape of the support structures 104 can be selected to present a reduced profile to wind currents or to visual appearance.

The length of the span member 108 can be selected to span the distance between opposing risers 112 so that the array 121 of solar cell modules 120 may substantially cover at least a portion of the waterway 150. In various implementations, the length of the span member 108 can be in a range from about 3 meter to about 50 meter, from about 10 meter to about 40 meter, from about 20 meter to about 30 meter, or some other range.

In some implementations, the support structure 104 can be formed as an integral unit. For example, the support structure 104 may be formed as a single tubular member. In other implementations, the support structure 104 can be formed from a plurality of sections that are assembled at the desired site, e.g., via welds, brackets, clamps, or fasteners. For example, the risers 112 and/or the span member 108 may comprise one or more sections. In some implementations, the sections of the support structure 104 comprise tubular members that may be generally similar to tubular members used to support overhead roadway signs. In other implementations, some or all of the sections may comprise metal beams (e.g., steel I-beams), trusses, reinforced concrete, wooden members, cement composites, or other structural building materials.

FIG. 1B schematically illustrates one or more deflectors 130 disposed near the risers 112. In the embodiment shown in FIG. 1B, the surface 134 of the deflector 130 is curved to help deflect airflow toward upper portions of the solar energy generation system 100. In other embodiments, the surface 134 may be slanted or segmented. The height of the deflector 130 can be in a range from about ¼ to ¾ of the height of the riser 112. In some implementations, the height of the deflector 130 may be about ½ the height of the riser 112. In other implementations, the height of the deflector 130 is substantially the same as the height of the riser 112.

In the embodiment shown in FIG. 1B, the deflector 130 is disposed adjacent the risers 112 and outside the support structure 104. In other embodiments, portions of the deflectors 130 can be disposed substantially between the risers 112 (see, e.g., FIG. 1A). In other implementations, some or all of the deflectors 130 may be disposed inside the support structure 104. Some or all of the deflectors 130 can be separate components that are disposed near or attached to the support structure 104. In other cases, some or all of the deflectors 130 may be formed integrally with the support structure 104 (e.g., as part of the risers 112). In some implementations, some or all of the deflectors 130 can be load-bearing elements that assist the support structure 104 in bearing the load of the solar cell modules 120. The deflectors 130 can be formed from substantially rigid construction materials such as, e.g., concrete or construction plastic (e.g., polyethylene). In other embodiments, portions of the deflectors 130 can be formed from tarp, sheeting, mesh, or other relatively thin material, which may have the possible advantage of being relatively light-weight and readily deployed at the site.

FIG. 1C is a cross-section view schematically illustrating an embodiment of a solar cell module 120. The solar cell module 120 includes one or more solar panels 124 supported by a housing 123 having a lower surface 122. The housing 123 may include one or more structural elements 126 to assist supporting the load of the solar panels 124. The solar cell module 120 can be elongated (see, e.g., FIG. 1A) and have a longitudinal axis (perpendicular to the plane shown in FIG. 1C).

The solar cell module 120 can have an aerodynamic cross-sectional shape (perpendicular to the longitudinal axis) that can help direct airflow across or past the solar cell modules 120 and that can provide an aerodynamic force F in a desired direction. For example, the solar cell module 120 can be shaped such that the aerodynamic force F on the module is directed generally downward, toward the ground, which may reduce the likelihood that the modules 120 are pulled off the support structure 104 during high wind conditions. In some implementations, the solar panel 124 may comprise a substantially planar array of one or more photovoltaic cells. The lower surface 122 of the housing 123 can have an arcuate shape, similar to an airfoil, to provide a desired amount or direction of aerodynamic force F for air flowing across the module 120. For example, FIG. 1C schematically illustrates an example of flow 132 of air past the solar cell module 120. Due at least in part to the arcuate shape of the lower surface 122, the flow speed across the surface 122 may be higher than the flow speed across the solar panels 124, which may result in an aerodynamic force F being directed downward, toward the ground. In some implementations, the cross-sectional shape of the solar cell modules 120 may also reduce or eliminate flutter that can be generated by flow 132 of air over the substantially flat solar panels 124, thereby reducing the dynamic load caused by the flow 132.

Portions of the housing 123 may be formed from metal (e.g., aluminum, steel, galvanized metal) or other substantially rigid materials. In some embodiments, the lower surface 122 comprises a plurality of perforations, openings, or holes that may advantageously reduce weight of the solar cell module 120 or improve drainage of liquids from the housing 123. In some such embodiments, portions of the lower surface 122 may comprise perforations that may be used to reduce or control the aerodynamic force F generated by the solar cell module 122. In some cases, the perforations may assist in dissipating or disrupting airflow past the lower surface 122. In some implementations, a perforated portion of the lower surface 122 can comprise metal fabric or mesh.

In some implementations, an arcuate shape of the lower surface 122 of the solar cell module 120 may help direct ambient precipitation toward the water 154 in the waterway 150. For example, water adhesion may help at least some of the precipitation flow along a portion of the lower surface 122 to a point that the flow separates or drops from the surface 122 toward the water 154. Thus, a possible advantage of some such implementations may be the ability for the system 100 to help direct a portion of the ambient precipitation into the waterway 150, which may improve water utilization or conservation.

One or more of the solar cell modules 120 can be disposed on the support structure 104 so that a normal 127 to the solar panels 124 may be oriented substantially perpendicular to the water 154 or the surface 160 (see, e.g., FIGS. 1A-1B). In other implementations, one or more of the solar cell modules 120 (or solar panels 124 of a particular module 120) may be oriented so that the normal 127 to a solar panel 124 points in a desired direction, e.g., to capture a greater amount of sunlight at the particular location of the solar panel for a particular time of year. In some implementations, some of the solar panels 124 are substantially planar, and the plane of the solar panel is oriented substantially parallel to the surface 160.

In one example implementation of the solar energy generation system 100, the distance between the risers 112 on opposite sides of the waterway 150 is about 30 meter. The support structures are spaced about 20 meter apart along a length of the waterway 150. The array 121 comprises 15 solar cell modules 120 having lengths of about 20 meter. The width of each solar cell module 120 is about 2 meter so that the array 121 substantially covers the waterway 150. In this example implementation, each solar cell module 120 comprises 22 solar panels 124, and each solar panel 124 has an area of about 1.25 meter² and can generate about 215 Watts of electrical power. Thus, for this example implementation, each solar cell module 120 can generate about 4.7 kWatt of electrical power, and the array of 15 modules can generate about 71 kWatt of electrical power. If this example implementation were deployed along 1 kilometer of the waterway 150, the solar energy generation system 100 could generate about 3.5 MWatt of electrical power, which could supply the annual electrical power needs for about 1000 homes in the U.S. Further, by shading the water 154 in the waterway 150 with the array 121 of solar cell modules 120, evaporation of the water 154 may be reduced by about 1-2 meter/year. The amount of water saved by reduced evaporation from the waterway 150 (for a 1 kilometer solar energy generation system 100) may be sufficient for the annual water consumption needs of several hundred people. Accordingly, embodiments of the solar energy generation system 100 can provide substantial consumer benefits for electrical power generation and for water savings. The foregoing example implementation is intended to illustrate certain aspects of one embodiment of the solar energy generation system 100 and is not intended to limit the scope of the disclosed systems.

### Example Embodiments of Solar Energy Generation Systems for Rights of Way

The example embodiment of the solar energy generation system 100 schematically illustrated in FIGS. 1A-1C can be adapted for use with or along public or private rights of way including, but not limited to, streets, roads, highways, sidewalks, walkways, pedestrian or bicycle paths, parking areas, bridges, railroad lines, magnetic levitation vehicle transport systems, public transportation networks (e.g., subways, shuttle ways, light rail lines, people movers, or mass transit systems), pipeline systems for transporting fluids (e.g., fuel, petroleum, oil, gas, water, slurries, sewage, or other liquids or gases), electric power transmission systems (e.g., high-tension power lines), and so forth. For example, rather than spanning the waterway 150, the support structure 104 can be used to span a portion of a highway, a railroad track, a pipeline, or other structure or right of way. Energy generated by the solar cell modules 120 may be used to provide electricity to power local electrical loads. For example, the generated electricity may be used to power (at least in part) lighting systems near a roadway, pumping systems for pumping fluids through a pipeline or for pumping water in the waterway, thermal control systems for regulating temperature of the fluids, or other electrical load. Some or all of the electricity generated during sunlight hours may be stored in an electrical storage system (e.g., rechargeable batteries, capacitors, or other electrical storage component) for use at other times (e.g., to power a lighting system at night). In some implementations, the generated electrical power can be used to provide power to vehicles that are at least partially electrically-powered (e.g., electric vehicles, hybrid vehicles) that may use the roadway or may be parked near the roadway for recharging. Embodiments of the solar energy generation system 100 can be used with any of the objects or structures described below with reference to FIG. 2.

In certain embodiments of the solar energy generation system 100 used with pipeline systems, such embodiments can assist in controlling the heat or viscosity of the fluid being transported by reducing or eliminating direct solar radiation of the pipeline thereby reducing heat input and, in turn, helping to control the temperature of the fluid. Also, for fluids that are to be heated in order to transport them, some embodiments of the system 100 can retard heat transmission from the heated fluid located within the pipeline to the heat sink of outer space during nighttime hours.

In certain embodiments of the solar energy generation system 100 used with right of ways (e.g., roadways, railways, or other rights of way described herein), the solar cell modules 120 may reduce the intensity of the sun's radiant energy onto vehicles traveling beneath the modules 120, thereby reducing the energy needed to cool the air (if desired) within the vehicles. Also, the cross-sectional shapes and relative locations of the solar cell modules 120 may disburse any possibly harmful effects of relatively high-pressure bow waves of air that can, in some cases, be generated by trains or other vehicles traveling at high speed under the solar energy generation system 100. Certain such embodiments may also help to disburse any possibly harmful effects of low-pressure tail waves of air that might be generated by trains or other vehicles traveling at high speed along under the system 100. In some implementations, at least a portion of the lower surface 122 of the solar cell module 120 comprises perforations, openings, or holes that may assist in dissipating pressure waves or shock waves that can be generated by passage of the high-speed vehicles. For example, a section of the lower surface 122 may be formed from metal fabric or mesh to provide the perforations.

In geographic areas of potential strong cross winds relative to the direction of a right of way, one or more deflectors 130 can be disposed substantially parallel to and along the length of the right of way potentially affected by strong cross winds. For example, deflectors 130 may be placed on one or both sides of the right of way. As discussed above, the deflectors 130 may help raise the path of airflow upward from the ground into the path of the wind that passes over the system 100. Deflecting ground level wind upward advantageously may reduce or eliminate strong cross winds over the right of way that could adversely affect the stability of vehicles operating along the right of way.

In certain embodiments, the support structure 104 can be disposed in a median strip between two rights of way (e.g., a median between two opposing directions of vehicle travel). Certain such embodiments may advantageously be used to shield passengers from the sun as well as to generate electrical power that can be used for general electrical needs or for local electrical loads (e.g., lighting, escalators, signage).

A high tension (high voltage) electrical power transmission line right of way can be used to transmit electrical power from a generator to a user at high voltage individually or as a part of the North American Power Grid. Certain embodiments of the solar energy generation system 100 can be used for covering at least some of the right of way area under high tension (voltage) electrical power transmission lines. The electrical power generated by the system 100 may be used locally or may be fed into the power grid or be used to replace line losses that occur when electricity is transmitted by the power lines over long distances. Further, when certain embodiments of the system 100 are used within rights of way under existing power transmission lines, the solar cell modules 120, which are elevated above the level of the surface 160 may act as a safety buffer to wildfires that could be caused by downed high power lines since the modules might be able to prevent broken power lines from touching and igniting vegetation fuel that might be present in the right of way.

### Example Embodiments of Solar Energy Generation Systems for Objects and Structures

FIG. 2 is a perspective view schematically illustrating an embodiment of a solar energy generation system 100 that comprises a solar assembly 200. Embodiments of the solar assembly 200 can be used to provide at least partial cover for one or more objects 210 that can be permanently or temporarily disposed (at least partially) under the support structure 104. The objects can include, but are not limited to, cargo, supplies, vehicles, airplanes, helicopters, buildings, structures, etc. The size and shape of the solar assembly 200 can be selected so that desired object(s) can fit (at least partially or completely) underneath the support structure 104 of the solar assembly 200. Embodiments of the solar assembly 200 can be used with any of the rights of way, transportation systems, or spaces described herein. As one example, embodiments of the solar assembly 200 can be used with the waterway 150 depicted in FIGS. 1A and 1B.

In the illustrated embodiment, the solar assembly 200 comprises two support structures 104a and 104b and an array 121 of solar cell modules 120 supported by the structures 104a, 104b. Respective ends of the solar cell modules 120 may be supported by respective support structures 104a, 104b using mounting fixtures 128. In other embodiments, one, three, four, five, six, or more support structures can be used to support the array 121. The support structures 104a, 104b and the solar cell modules 120 may be generally similar to any of the embodiments of the support structures 104 and solar cell modules 120 described with reference to FIGS. 1A-1C. For example, the support structure 104a may comprise risers 112a, 112b and span member 108a. Lower ends of the risers 112 can be mounted in, anchored, or attached to foundation footers 204, which can be sunk in the ground or surface on which the solar energy generation system 100 is to be disposed. In some embodiments, the foundation footers 204 are sunk to a depth that is approximately equal to the height of the risers 112.

The solar cell modules 120 can be used to provide electrical power to the objects 210 or to other objects in the vicinity of the solar assembly, to provide electrical power to an energy storage system or energy transmission system, and so forth. The array 121 of solar cell modules 120 can be used to at least partially shade the object(s) 210 disposed underneath the solar assembly 200.

The solar assembly 200 may, but need not, include one or more deflectors 130 (not shown in FIG. 2) if it is desired to at least partially deflect airflow near the ground toward upper portions of the system 100. Implementations in which deflectors are used advantageously may at least partially shield objects disposed under the system 100 from environmental conditions (e.g., wind, rain, or snow).

### Example Embodiments of Solar Ener Generation System Kits

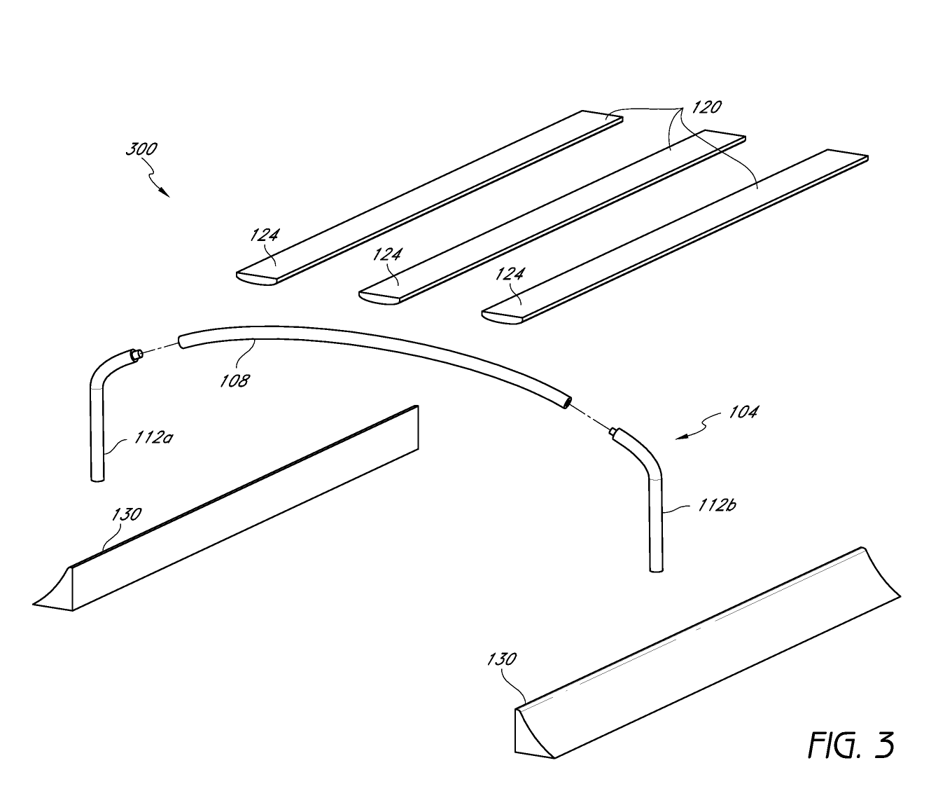

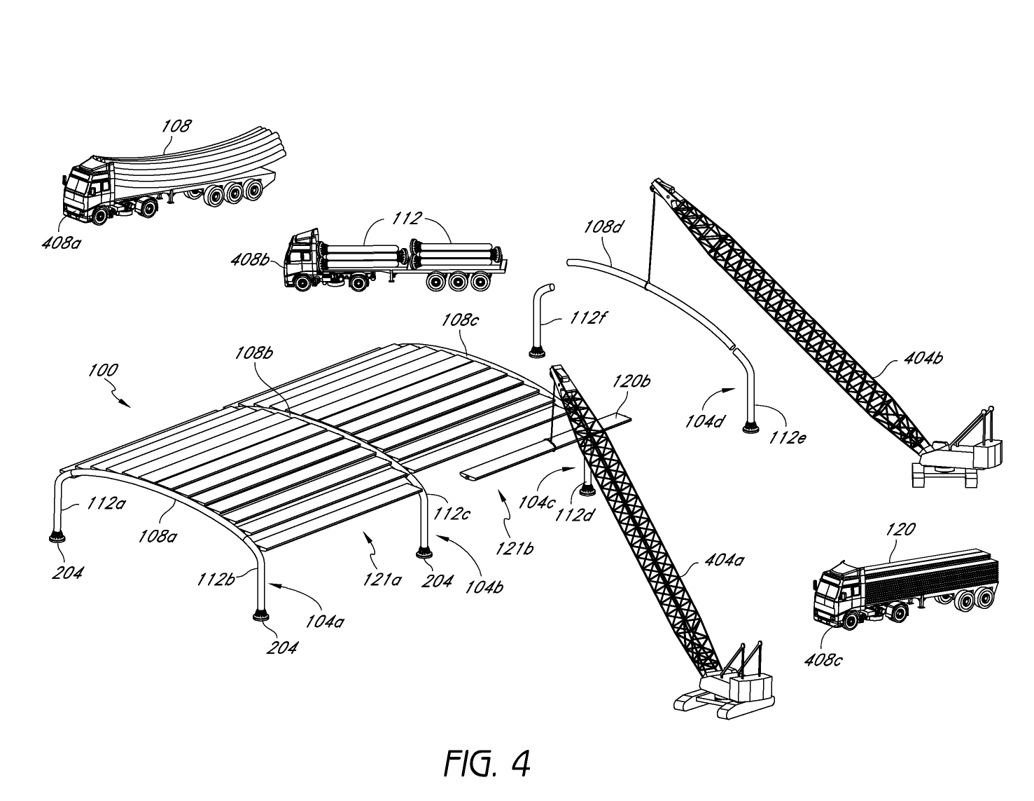

With reference to FIG. 3, in some implementations, a kit 300 comprises components that can be used for assembly of embodiments of the solar energy generation system 100 or solar assembly 200. In the embodiment shown in FIG. 3, the kit 300 comprises risers 112a, 112b, span member 108, a plurality of solar cell modules 120 comprising solar panels 124, and a plurality of deflectors 130. In other embodiments, the kit 300 may comprise additional or different components than shown in FIG. 3. Further, the components of the kit 300 may be configured differently than shown in FIG. 3. For example, the risers 112a, 112b, the span member 108, the solar cell modules 120, the solar panels 124, or the deflectors 130 may be provided in sections that can be assembled at the work site (see, e.g., FIG. 4).

The components in the kit 300 can be selected, sized, or shaped for the particular implementation of the solar energy generation system 100 or solar assembly 200. For example, in some embodiments, the kit 300 may be adapted to be shipped by air transport to a work site, and each of the components of the kit 300 may be configured to fit within an appropriate cargo aircraft (e.g., C-5, C-17, C-130, C-141, or A400M aircraft). In some embodiments, the kit 300 may be configured to be used with a suitable container or pallet (e.g., a unit load device) for air, land, or sea transport. In various implementations, the kit 300 can be configured for transport via truck, rail, ship, or other military or commercial transport.

### Example Methods for Assembly of Solar Energy Generation sy

FIG. 4 schematically illustrates an example of the assembly of an embodiment of a solar energy generation system 100. In this example, support structures 104a-104c have been assembled and have been being mounted, anchored, or attached to suitable foundation footers 204 in or on the surface of the work site. The array 121a of solar cell modules has been mounted to the support structures 104a, 104b, and the array 121b is in the process of assembly. FIG. 4 schematically illustrates a solar cell module 120b being lowered into place in the array 121b by a crane 404a.

In this illustrative example, each of the support structures 104a-104d comprises a pair of risers and a span member mounted between the pair of risers. FIG. 4 schematically shows risers 112a-112f mounted, anchored, or attached to the surface, and span member 108d being lowered into position between the risers 112e and 112f by crane 404b. Transports 408a, 408b, and 408c are schematically shown bringing additional components (e.g., of a kit 300) of the solar energy generation system 100 (e.g., risers 112, span members 108, and solar cell modules 120) to the worksite.

FIG. 4 is intended as a non-limiting illustration of one possible example of the assembly of an embodiment of the solar energy generation system 100. In other implementations, the system 100 may be fabricated, assembled, constructed, anchored, or mounted differently than shown in FIG. 4.

Reference throughout this specification to “some embodiments” or “an embodiment” means that a particular feature, structure, element, act, or characteristic described in connection with the embodiment is included in at least one embodiment. Thus, appearances of the phrases “in some embodiments” or “in an embodiment” in various places throughout this specification are not necessarily all referring to the same embodiment and may refer to one or more of the same or different embodiments. Furthermore, the particular features, structures, elements, acts, or characteristics may be combined in any suitable manner, as would be apparent to one of ordinary skill in the art from this disclosure, in one or more embodiments. Further, in various embodiments, features, structures, elements, acts, or characteristics can be combined, merged, rearranged, reordered, or left out altogether. Thus, no single feature, structure, element, act, or characteristic or group of features, structures, elements, acts, or characteristics is necessary or required for each embodiment. All possible combinations and subcombinations are intended to fall within the scope of this disclosure.

As used in this application, the terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Similarly, it should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Rather, inventive aspects lie in a combination of fewer than all features of any single foregoing disclosed embodiment.

The foregoing description sets forth various example embodiments and other illustrative, but non-limiting, embodiments of the inventions disclosed herein. The description provides details regarding combinations, modes, and uses of the disclosed inventions. Other variations, combinations, modifications, equivalents, modes, uses, implementations, and/or applications of the disclosed features and aspects of the embodiments are also within the scope of this disclosure, including those that become apparent to those of skill in the art upon reading this specification. Additionally, certain objects and advantages of the inventions are described herein. It is to be understood that not necessarily all such objects or advantages may be achieved in any particular embodiment. Thus, for example, those skilled in the art will recognize that the inventions may be embodied or carried out in a manner that achieves or optimizes one advantage or group of advantages as taught herein without necessarily achieving other objects or advantages as may be taught or suggested herein. Also, in any method or process disclosed herein, the acts or operations making up the method or process may be performed in any suitable sequence and are not necessarily limited to any particular disclosed sequence.

What is claimed is:

1. A solar energy generation system adapted for use with a right of way, the solar energy generation system comprising:
a plurality of support structures disposed along a length of a right of way, each of the plurality of support structures spaced from each other along the length of the right of way, each of the support structures comprising a first riser portion disposed on a first side of the right of way, a second riser portion disposed on a second side of the right of way, and a span portion extending from the first riser portion and the second riser portion above a surface of the right of way;
a plurality of solar cell modules disposed substantially parallel to each other along the length of the right of way, each solar cell module at least partially supported above the right of way by at least some of the span portions of the plurality of support structures, each solar cell module comprising one or more photovoltaic panels configured to receive sunlight and generate electricity, each solar cell module having a cross-sectional shape configured to generate an aerodynamic force directed toward the surface of the right of way in the presence of airflow past the solar cell module; and
one or more deflectors disposed adjacent at least some of the first riser portions disposed on the first side of the right of way, the one or more deflectors disposed substantially parallel to the length of the right of way, the one or more deflectors configured to at least partially deflect airflow away from the surface of the right of way.

2. The solar energy generation system of claim 1, wherein the right of way comprises a waterway.

3. The solar energy generation system of claim 2, wherein the waterway comprises an aqueduct.

4. The solar energy generation system of claim 1, wherein the right of way comprises a roadway, a railroad right of way, a pipeline right of way, or an electrical transmission right of way.

5. The solar energy generation system of claim 1, wherein a center section of the span portion has a shape that comprises a portion of a curve that is substantially elliptical.

6. The solar energy generation system of claim 1, wherein a lower end of at least one of the first riser portion and the second riser portion is mounted in or on or attached to a foundation footer.

7. The solar energy generation system of claim 6, wherein the foundation footer is formed in undeveloped portion of the surface of the right of way.

8. The solar energy generation system of claim 1, wherein at least one of the first riser portion and the second riser portion is disposed substantially perpendicular to the surface of the roadway.

9. The solar energy generation system of claim 1, wherein at least some of the support structures comprise elongated tubular members.

10. The solar energy generation system of claim 1, wherein each solar cell module comprises a housing, an upper portion of the housing comprising the one or more photovoltaic panels, and a lower portion of the housing comprising a surface having an arcuate shape.

11. The solar energy generation system of claim 10, wherein the lower portion of the housing comprises a perforated region.

12. The solar energy generation system of claim 1, wherein at least one photovoltaic panel of a solar cell module is oriented such that a normal to the photovoltaic panel is substantially perpendicular to the surface of the right of way.

13. The solar energy generation system of claim 1, further comprising one or more deflectors disposed adjacent at least some of the second riser portions disposed on the second side of the right of way.

14. The solar energy generation system of claim 1, wherein at least a portion of some of the one or more deflectors is disposed between adjacent first riser portions.

15. The solar energy generation system of claim 1, wherein at least some of the one or more deflectors comprise a curved surface configured to at least partially deflect airflow toward the span portions.

16. The solar energy generation system of claim 1, wherein the right of way comprises a waterway, and one or more deflectors are configured to inhibit airflow past a surface of water in the waterway, thereby reducing evaporation of water from the waterway.

17. The solar energy generation system of claim 1, wherein the plurality of solar cell modules are disposed to substantially cover at least a portion of the right of way between the first side and the second side.

18. A solar assembly comprising:
a first support member having a first portion disposed above a surface;
a second support member spaced from the first support member along a first direction, the second support member having a second portion disposed above the surface; and
a solar array comprising a plurality of solar cell modules, each solar cell module comprising at least one photovoltaic panel, each solar cell further comprising a first end portion and a second end portion, the first end portion mounted or attached to the first portion of the first support member, the second end portion mounted or attached to the second portion of the second support member, each of the solar cell modules oriented substantially parallel to the first direction, each solar cell module having a cross-sectional shape in a plane perpendicular to the first direction, the cross-sectional shape configured to generate an aerodynamic force directed toward the surface in the presence of an airflow at least partially flowing perpendicular to the first direction.

19. The solar assembly of claim 18, wherein at least one of the first support member and the second support member comprises a central portion having a shape that comprises a portion of a curve that is substantially elliptical.

20. The solar assembly of claim 18, wherein at least one of the first support member and the second support member comprises an arch-shaped central portion.

21. The solar assembly of claim 18, further comprising a deflector oriented substantially parallel to the first direction, the deflector having a deflector surface configured to at least partially deflect an airflow at least partially flowing perpendicular to the first direction away from the surface.

22. The solar assembly of claim 18, wherein the first support member comprises at least one riser configured to at least partially support the first portion of the support member above the surface.

23. A kit of components adapted for assembly of a solar energy generation system, the kit comprising:
at least one support structure, the support structure comprising at least one riser and at least one span member, the riser having a first end portion configured for mounting or attachment to a surface and a second end portion configured to at least partially support the span member;
at least one elongated solar cell module having a longitudinal axis, the solar cell module having at least one end portion configured to be mounted or attached to a span member, the solar cell module having an upper portion and a lower portion, the upper portion configured to at least partially support at least one photovoltaic panel, the solar cell module having a shape in a plane perpendicular to the longitudinal axis that is configured to generate an aerodynamic force in the presence of air flowing at least partially perpendicular to the longitudinal axis, the aerodynamic force having a component directed away from the upper portion of the solar cell module.

24. The kit of claim 23, further comprising at least one photovoltaic panel.

25. The kit of claim 23, wherein the span member has shape that comprises a portion of a curve that is substantially elliptical.

26. The kit of claim 23, further comprising at least one deflector, the deflector configured to at least partially deflect airflow away from the surface.
